(19) United States
(12) Patent Application Publication
(10) Pub. No.: US 2026/0160817 A1
(43) Pub. Date: Jun. 11, 2026

(54) METHOD FOR MANUFACTURING BATTERY AND METHOD FOR TESTING BATTREY

(71) Applicant: Prime Planet Energy & Solutions, Inc., Tokyo (JP)

(72) Inventor: Isao ODA, Neyagawa-shi (JP)

(21) Appl. No.: 19/405,397

(22) Filed: Dec. 2, 2025

(30) Foreign Application Priority Data
Dec. 5, 2024 (JP) 2024-212127

(51) Int. Cl. G01R 31/3835; H01M 4/04

(52) U.S. Cl. CPC G01R 31/3835; H01M 4/0447

(57) ABSTRACT

A method for manufacturing a battery includes steps of performing aging processing on multiple batteries, acquiring an inter-terminal voltage before the aging processing for the multiple batteries, acquiring an inter-terminal voltage after the aging processing for the multiple batteries, and determining, for each of the multiple batteries, whether the battery is defective. In the step of determining, a threshold is set based on inter-terminal voltage differences between the inter-terminal voltages before and after the aging processing for the multiple batteries, excluding at least one inter-terminal voltage difference.

### CROSS REFERENCE OF RELATED APPLICATION

The present application claims priority from Japanese Patent Application No. 2024-212127 filed on Dec. 5, 2024, which is incorporated by reference herein in its entirety.

### BACKGROUND

The present disclosure relates to a method for manufacturing a battery and a method for testing a battery.

JP 2006-253027 A discloses a method for manufacturing a battery, the method including determining a defect of a secondary battery and determining a defect of a secondary battery for some other secondary batteries excluding the secondary battery a defect thereof has been determined.

### SUMMARY

In manufacturing a battery, a defect of a battery is determined based on electrical properties of multiple batteries in some cases.

A method for manufacturing a battery disclosed herein includes steps of performing aging processing on multiple batteries, acquiring an inter-terminal voltage before the aging processing for the multiple batteries, acquiring an inter-terminal voltage after the aging processing for the multiple batteries, and determining, for each of the multiple batteries, whether the battery is defective. In the step of determining, a threshold is set based on inter-terminal voltage differences between the inter-terminal voltages before and after the aging processing for the multiple batteries, excluding at least one inter-terminal voltage difference. According to the method for manufacturing a battery described above, accuracy in determining a defect of the battery is increased.

### BRIEF DESCRIPTION OF THE DRAWINGS

FIG. 1 is a flowchart of a method for manufacturing a battery.

FIG. 2 is a cross-sectional view schematically illustrating an internal structure of a battery 1.

FIG. 3 is a schematic view of an electrode body 20.

FIG. 4 is a flowchart of a determining step S30.

FIG. 5 is a graph illustrating an inter-terminal voltage difference ΔV after aging processing.

FIG. 6 is a graph illustrating the inter-terminal voltage difference ΔV after aging processing.

FIG. 7 is a graph illustrating the inter-terminal voltage difference ΔV after a defective battery 1 is excluded.

FIG. 8 is a graph illustrating the inter-terminal voltage difference ΔV after the defective battery 1 is excluded.

FIG. 9 is a graph illustrating the inter-terminal voltage difference ΔV after the defective battery 1 is excluded according to another embodiment.

### DETAILED DESCRIPTION OF THE EMBODIMENTS

Embodiments of a technology disclosed herein will be described below with reference to the accompanying drawings. As a matter of course, the embodiments described herein are not intended to be particularly limiting the present disclosure. The accompanying drawings are schematic and do not necessarily reflect actual members or portions. Members/portions that have the same effect will be denoted by the same sign as appropriate, and the overlapping description will be omitted as appropriate. In this specification, the notation “X to Y” or the like that indicates a numerical range means “X or more and Y or less,” unless specifically stated otherwise.

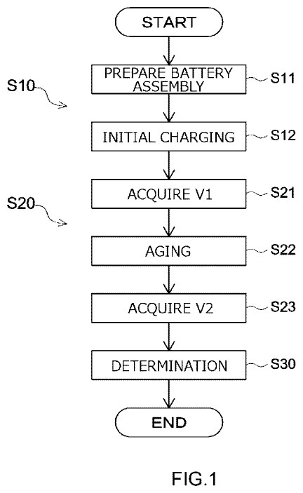

FIG. 1 is a flowchart of a method for manufacturing a battery. As illustrated in FIG. 1, the method for manufacturing a battery includes a step S10 of preparing multiple batteries and a step S20 of determining a defect of a battery. The method for manufacturing a battery may include some other step. The method for manufacturing a battery will be described below using a lithium-ion secondary battery as an example. Note that a technology disclosed herein is not limited to a method for manufacturing a lithium-ion secondary battery, and is also applicable to some other known battery (for example, a sodium ion secondary battery or the like).

### Step S10 of Preparing Multiple Batteries

In a step S10 of preparing multiple batteries, multiple batteries 1 are prepared in accordance with a known method. As illustrated in FIG. 1, the step S10 of preparing multiple batteries includes a battery assembly preparing step S11 and an initial charging step S12.

### Battery Assembly Preparing Step S11

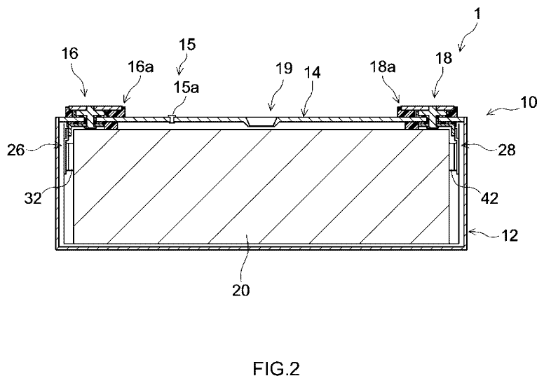

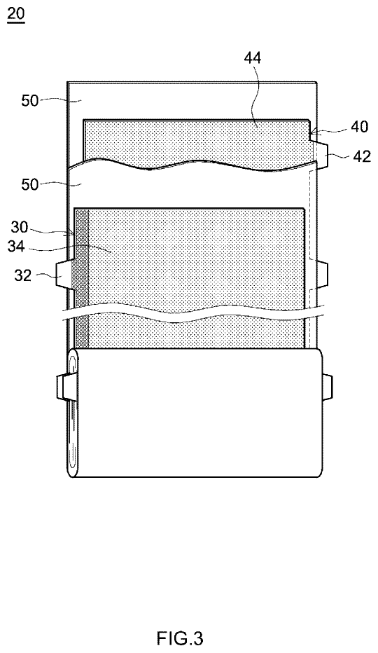

In the battery assembly preparing step S11, a battery assembly 1 before initial charging is prepared. FIG. 2 is a cross-sectional view schematically illustrating an internal structure of the battery 1. FIG. 3 is a schematic view of an electrode body 20. In the battery assembly preparing step S11, a case 10, the electrode body 20, and a nonaqueous electrolyte (not illustrated) are prepared.

As illustrated in FIG. 2, the case 10 is a rectangular container. For the case 10, for example, a metal material (aluminum, an aluminum alloy, or the like) having a certain strength is used. The case 10 includes a case body 12 having an opening in an upper portion and a lid 14 that closes the opening. The electrode body 20 and an electrolytic solution are housed in the case 10. An injection port 15 through which the electrolytic solution is injected is provided at the lid 14. The lid 14 is provided with a gas exhaust valve 19. Each of a positive electrode terminal 16 and a negative electrode terminal 18 is attached to the lid 14 via a corresponding one of instating members 16a and 18a. Each of the positive electrode terminal 16 and the negative electrode terminal 18 is connected to the electrode body 20 via a corresponding one of current collectors 26 and 28 provided inside the case 10. As the positive electrode terminal 16, aluminum, an aluminum alloy, or the like can be used. As the negative electrode terminal 18, copper, a copper alloy, or the like can be used.

The electrode body 20 is an electricity generation element of the battery 1. As FIG. 3, the electrode body 20 includes a positive electrode plate 30, a negative electrode plate 40, and a separator 50. In this embodiment, the electrode body 20 is a wound electrode body. The wound electrode body is formed by stacking the positive electrode plate 30, the negative electrode plate 40, and the separator 50 and winding an obtained stacked body. There is no particular limitation on a structure of the electrode body 20 and the electrode body 20 may be some other known structure (a stacked electrode body or the like).

The positive electrode plate 30 includes a positive electrode core 32 that is a metal foil having conductivity and a positive electrode active material layer 34 formed on a surface of the positive electrode core 32. Aluminum or the like is used for the positive electrode core 32. The positive electrode active material layer 34 includes a positive electrode material, a conductive material, a binder, or the like. As a positive electrode active material, for example, lithium-transition metal compound oxide can be used. As the conductive material, a carbon material, such as acetylene black, graphite, or the like, can be used. As the binder, a resin material, such as polyvinylidene fluoride (PVdF) or the like, can be used.

The negative electrode plate 40 includes a negative electrode core 42 that is a metal foil having conductivity and a negative electrode active material layer 44 given on a surface of the negative electrode core 42. Copper or the like is used for the negative electrode core 42. The negative electrode active material layer 44 includes a negative electrode material, a binder, a thickener, or the like. As a negative electrode active material, a carbon material, such as graphite, hard carbon, soft carbon, or the like, can be used. As the binder, a resin material, such as styrene butadiene rubber (SBR) or the like, can be used. As the thickener, a resin material, such as carboxymethyl cellulose (CMC) or the like, can be used.

The separator 50 is an insulating sheet interposed between the positive electrode plate 30 and the negative electrode plate 40. As the separator 50, for example, a resin material, such as polyethylene (PE), polypropylene (PP), polyester, cellulose, polyamide, or the like, can be used. A heat-resistant layer including an in organic filler may be formed on a surface of the separator 50.

The electrolytic solution includes a nonaqueous solvent and a supporting salt. As the nonaqueous solvent, for example, ethylene carbonate (EC), diethyl carbonate (DEC), dimethyl carbonate (DMC), ethyl methyl carbonate (EMC), or the like, can be used. As the supporting salt, various lithium salts can be used, and, for example, LiPF₆ or the like can be used.

In the battery assembly preparing step S11, the battery assembly 1 is prepared by having the electrode body 20 housed in the prepared case 10 and injecting the electrolytic solution (see FIG. 2). After injecting the electrolytic solution, the injection port 15 is sealed with a sealing member 15a. In the battery assembly preparing step S11, multiple battery assemblies 1 are prepared.

### Initial Charging Step S12

In the initial charging step S12, initial charging is performed on the multiple battery assemblies 1. In the initial charging step S12, each of the battery assemblies 1 is charged under a predetermined condition until a voltage of the battery assembly 1 reaches a predetermined voltage value. Initial charging can be performed by a known method. The voltage value can be selected to be about 10% to 90% with respect to a state of charge (SOC) when the battery assembly 1 is fully charged, although there is no particular limitation thereon. Initial charging can be performed, for example, in an ordinary temperature environment at about 25° C. (for example, about 20° C. to 30° C.) and a charging rate of about 0.05 C to 10 C, although there is no particular limitation thereon. Note that the voltage value, the charging condition, or the like of initial charging are set in accordance with a type of a battery or the like. In the initial charging step S12, initial charging is individually performed on each of the multiple battery assemblies 1.

Initial charging is performed on the multiple battery assemblies 1, and thus, the multiple batteries 1 are prepared. When the multiple batteries 1 are prepared, subsequently, whether there is a defect in any one of the multiple batteries 1 is determined. Note that the initial charging step S12 may include a step of repeating charging and discharging on the battery 1 under a predetermined condition. The battery 1 is activated by the initial charging step S12 described above.

### Step S20 of Determining Defect of Battery

The step S20 of determining a defect of a battery is performed based on inter-terminal voltages before and after aging of the battery 1. As illustrated in FIG. 1, the step S20 of determining a defect of a battery includes a first inter-terminal voltage acquiring step S21, an aging processing step S22, a second inter-terminal voltage acquiring step S23, and a determining step S30.

### First Inter-Terminal Voltage Acquiring Step S21

In the first inter-terminal voltage acquiring step S21, an inter-terminal voltage (first inter-terminal voltage) V1 before aging processing is acquired for the multiple batteries 1. At this time, each of the multiple batteries 1 has been charged to a predetermined voltage (or a voltage corresponding to a predetermined SOC). There is no particular limitation on the voltage and SOC of each of the multiple batteries 1 in the initial charging step S12. The battery 1 may be charged to the predetermined voltage in the initial charging step S12. The voltage of the battery 1 may be adjusted to be the predetermined voltage after the initial charging step S12.

The first inter-terminal voltage V1 can be measured by an unillustrated voltage measuring device. A positive electrode terminal and a negative electrode terminal of the voltage measuring device can be connected to the positive electrode terminal 16 and negative electrode terminal 18 of each of the batteries 1, respectively, to measure the first inter-terminal voltage V1. Note that, in the first inter-terminal voltage acquiring step S21, when there is a battery the first inter-terminal voltage V1 of which is out of a predetermined range, the battery may be excluded as a defective battery. The excluded battery 1 is excluded also in the following steps. After the first inter-terminal voltage acquiring step S21, aging processing is performed on the multiple batteries 1.

### Aging Processing Step S22

In the aging processing step S22, aging processing is performed on the multiple batteries 1. In the aging processing step S22, the multiple batteries 1 are stored in an unillustrated aging device and is placed under an environment at a predetermined temperature for a predetermined period. The multiple batteries 1 may be aged in a single aging device and may be aged in different aging devices. An aging condition is set in accordance with a battery type or the like, and there is no particular limitation thereon. An aging temperature can be set to a certain temperature selected from a range of about 20° C. to 75° C. An aging period can be set to about five to fifteen days. After aging processing, the inter-terminal voltage is acquired for the multiple batteries 1 again.

### Second Inter-Terminal Voltage Acquiring Step S23

In the second inter-terminal voltage acquiring step S23, an inter-terminal voltage (second inter-terminal voltage) V2 after aging processing is acquired for the multiple batteries 1. A method for acquiring the second inter-terminal voltage V2 may be similar to a method for acquiring the first inter-terminal voltage V1. Note that, in the second inter-terminal voltage acquiring step S23, when there is a battery the second inter-terminal voltage V2 of which is out of a predetermined range, the battery may be excluded as a defective battery. The excluded battery 1 is excluded also in the following steps.

After aging processing, the inter-terminal voltages of the multiple batteries 1 have been reduced to be lower than the inter-terminal voltages before aging processing. In other words, the second inter-terminal voltage V2 is lower than the first inter-terminal voltage V1. Whether each of the multiple batteries 1 is defective is determined based on the first inter-terminal voltage V1 and the second inter-terminal voltage V2.

### Determining Step S30

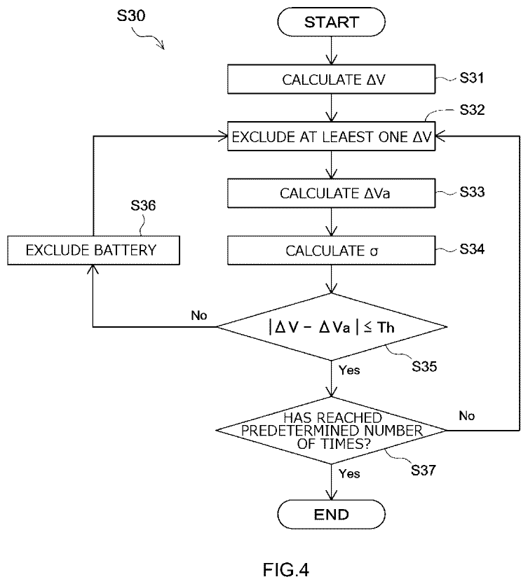

In the determining step S30, whether the battery is defective is determined for each of the multiple batteries 1, based on the inter-terminal voltage difference V1−V2 (ΔV) before and after aging processing acquired for each of the multiple batteries 1. FIG. 4 is a flowchart of the determining step S30. As illustrated in FIG. 4, the determining step S30 includes a step S31 of calculating the inter-terminal voltage difference for the multiple batteries, a step S32 of excluding at least one inter-terminal voltage difference, a step S33 of calculating an average value of the inter-terminal voltage differences, a step S34 of calculating a standard deviation of the inter-terminal voltage differences, a step S35 of determining a defect of a battery, based on a threshold, a step S36 of excluding a battery that has been determined to be defective, and a step S37 of determining whether determination of a defect has been repeated a predetermined number of times. Herein, N batteries 1 are targets of determination in the determining step S30. Herein, N is an integer. Note that there is no particular limitation on the number of batteries that are targets of determination.

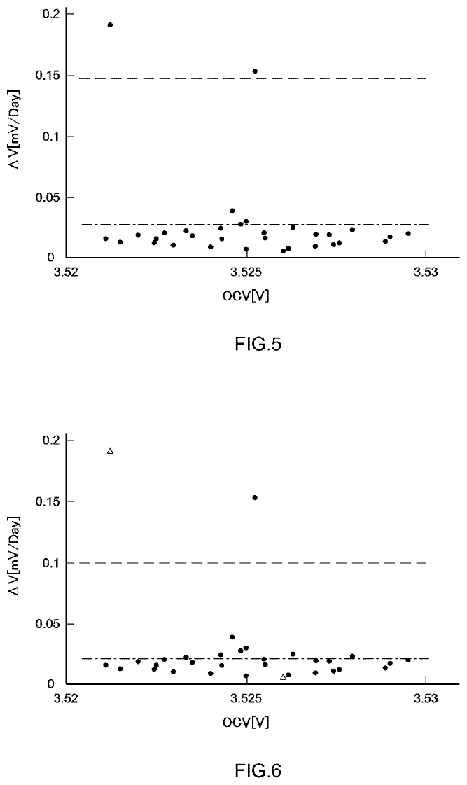

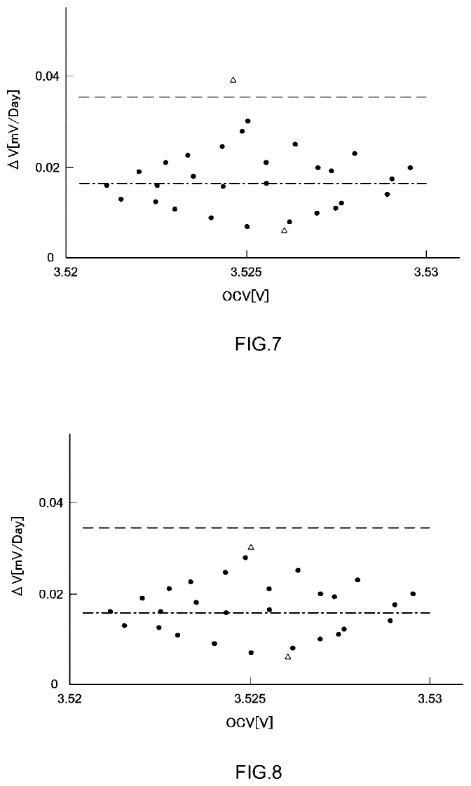

FIG. 5 and FIG. 6 are graphs each illustrating the inter-terminal voltage difference ΔV after aging processing. In FIG. 5 and FIG. 6, for each of the multiple batteries 1 the inter-terminal voltage difference ΔV of which has been calculated, an open circuit voltage (OCV) after aging processing and the inter-terminal voltage difference ΔV are indicated. In FIG. 5, all of the inter-terminal voltages ΔV of the multiple batteries 1 are indicated by circles. FIG. 7 and FIG. 8 are graphs illustrating the inter-terminal voltage differences ΔV after excluding defective batteries 1. FIG. 7 is a graph illustrating the inter-terminal voltage differences ΔV after excluding defective batteries 1 at a first time. FIG. 8 is a graph illustrating the inter-terminal voltage differences ΔV after excluding defective batteries 1 at a second time. In each of FIG. 5 to FIG. 8, an average value ΔVa of the inter-terminal voltage differences ΔV is indicated by a dashed-dotted line and a threshold Th set with the average value ΔVa as a reference is indicated by a broken line. In each of FIG. 6 to FIG. 8, of the inter-terminal voltage differences ΔV of the multiple batteries 1, the inter-terminal voltage difference ΔV that is excluded in the step S32 is indicated by a triangle and the inter-terminal voltage difference ΔV that is not excluded in the step S32 is indicated by a circle.

### Step S31 of Calculating Inter-Terminal Voltage Difference for Battery 1

In the step S31 of calculating the inter-terminal voltage difference for the battery 1, the inter-terminal voltage difference ΔV is calculated from a difference between the first inter-terminal voltage V1 and the second inter-terminal voltage V2. Herein, the inter-terminal voltage difference ΔV is calculated for each of the multiple batteries 1. In this embodiment, the inter-terminal voltage difference ΔV is calculated for the N batteries 1 (see FIG. 5). The inter-terminal voltage difference ΔV is a value obtained by dividing the difference between the first inter-terminal voltage V1 and the second inter-terminal voltage V2 by the aging period (the number of days). Note that a method for calculating the inter-terminal voltage difference ΔV is not limited to a calculation method described above. The inter-terminal voltage difference ΔV may be, for example, a difference between the first inter-terminal voltage V1 and the second inter-terminal voltage V2, not the value obtained by dividing the difference by the aging period.

### Step S32 of Excluding at Least One Inter-Terminal Voltage Difference

In the step S32 of excluding at least one inter-terminal voltage difference, of the inter-terminal voltage differences ΔV calculated for the multiple batteries 1 (N batteries 1 in this embodiment) that are targets of determination, at least one inter-terminal voltage difference ΔV is excluded from subsequent calculations (in this embodiment, calculation of the average value (S33) and calculation of the standard deviation (S34)).

In an embodiment illustrated in FIG. 5, the average value of the inter-terminal voltage differences ΔV (mV/Day) of the multiple batteries 1 is 0.0272 and the deviation value is 0.0390. As illustrated in FIG. 6, of the inter-terminal voltage differences ΔV of the multiple batteries 1, a maximum value ΔVmax and a minimum value ΔVmin are excluded. Herein, of the inter-terminal voltage differences ΔV of the N batteries 1, the maximum and minimum inter-terminal voltage differences ΔV are excluded. The threshold Th used for determining a defect of the battery 1 is set based on the inter-terminal voltage differences ΔV of remaining (N−2) batteries.

### Step S33 of Calculating Average Value of Inter-Terminal Voltage Differences

In the step S33 of calculating the average value of the inter-terminal voltage differences, the average value ΔVa of the inter-terminal voltage differences ΔV of the batteries 1 is calculated. Herein, the average value of the inter-terminal voltage differences ΔV of the (N−2) batteries 1, excluding the maximum value ΔVmax and the minimum value ΔVmin, is calculated. In this embodiment, the average value ΔVa is 0.0224.

### Step S34 of Calculating Standard Deviation of Inter-Terminal Voltage Differences>

In the step S34 of calculating the standard deviation of the inter-terminal voltage differences, a standard deviation σ of the inter-terminal voltage differences ΔV of the batteries 1 is calculated. Herein, similar to the step S33 of calculating the average value, the standard deviation σ of the inter-terminal voltage differences ΔV of the (N−2) batteries 1, excluding the maximum value ΔVmax and the minimum value ΔVmin, is calculated. In this embodiment, the standard deviation σ is 0.0257.

### Step S35 of Determining Defect of Battery 1 Based On Threshold

In the step S35 of determining a defect of the battery 1 based on the threshold, whether the battery 1 is defective is determined based on the predetermined threshold TH. In this embodiment, the threshold Th is set for the inter-terminal voltage differences ΔV excluding at least one inter-terminal voltage difference ΔV (the maximum value ΔVmax and the minimum value ΔVmin). Herein, whether the battery 1 is defective is determined for all of the N batteries 1 that are targets of determination.

The threshold Th is set based on the standard deviation σ calculated in the step S34 of calculating the standard deviation. The threshold Th can be determined to a value (nσ) obtained by multiplying the standard value σ by a value n. The value n can be set by a mass production test in accordance with a battery type, or the like. In this embodiment, the threshold Th is set to a value (3σ) that is three times the standard deviation σ. Nota that the threshold Th is not limited thereto.

Whether the battery 1 is defective is determined based on the threshold Th for all of the N batteries 1. Herein, whether a difference between the inter-terminal voltage difference ΔV and the average value ΔVa calculated in the step S33 of calculating the average value is equal to or less than the threshold Th is determined for each of the batteries 1. As illustrated in FIG. 6, in each of the (N−2) batteries 1 of the N batteries 1, the difference between the inter-terminal voltage difference ΔV and the average value ΔVa is equal to or less than the threshold Th. In the battery 1 the inter-terminal voltage difference ΔV of which is highest and the battery 1 the inter-terminal voltage difference ΔV of which is second highest of the N batteries, the difference between the inter-terminal voltage difference ΔV and the average value ΔVa is larger than the threshold Th. The battery 1 the inter-terminal voltage difference ΔV of which is highest and the battery 1 the inter-terminal voltage difference ΔV of which is second highest are determined to be defective. When it is determined that there is the defective battery 1 (NO), the process proceeds to the step S36.

### Step S36 of Excluding Battery Determined to Be Defective

In the step S36 of excluding the battery determined to be defective, the two batteries 1 determined to be defective among the N batteries 1 that are targets of determination are excluded from the targets of determination. After the two batteries 1 are excluded from the targets of determination, the process returns to the step S32 of excluding at least one inter-terminal voltage difference.

### Step S32 of Excluding at Least One Inter-Terminal Voltage Difference

In the step S32 of excluding at least one inter-terminal voltage difference that is performed at a second time, similar to the step S32 performed at a first time, at least one inter-terminal voltage difference ΔV of the inter-terminal voltage differences ΔV calculated for the multiple batteries 1 is excluded from subsequent calculations. Two batteries 1 are excluded from targets of determination in the step S36. Herein, similar to the step S32 performed at the first time, the maximum and minimum inter-terminal voltage differences ΔV of the inter-terminal voltage differences ΔV of the (N−2) batteries 1 are excluded. The threshold Th used for determining a defect of the battery 1 is set based on the inter-terminal voltage differences ΔV of remaining (N−4) batteries 1.

As illustrated in FIG. 7, of the inter-terminal voltage differences ΔV of the multiple batteries 1, the maximum value ΔVmax and the minimum value ΔVmin are excluded. Herein, of the inter-terminal voltage differences ΔV of the (N−2) batteries 1, the maximum and minimum inter-terminal voltage differences ΔV are excluded. The threshold Th used for determining a defect of the battery 1 is set again based on the inter-terminal voltage differences ΔV of the remaining (N−4) batteries 1. Note that the minimum ΔVmin is the same as that excluded in the step S32 that has been performed at the first time.

### Step S33 of Calculating Average Value of Inter-Terminal Voltage Difference

In the step S33 of calculating the average value of the inter-terminal voltage differences that is performed at a second time, the average value of the inter-terminal voltage differences ΔV of the (N−4) batteries 1, excluding the maximum value ΔVmax and the minimum value ΔVmin, is calculated. In this embodiment, the average value ΔVa is 0.0171.

### Step S34 of Calculating Standard Deviation of Inter-Terminal Voltage Difference

In the step S34 of calculating the standard deviation of the inter-terminal voltage differences that is performed at a second time, similar to the step S33 of calculating the average value, the standard deviation σ of the inter-terminal voltage differences ΔV of the (N−4) batteries, excluding the maximum value ΔVmax and the minimum value ΔVmin, is calculated. In this embodiment, the standard deviation σ is 0.0060.

### Step S35 of Determining Defect of Battery 1 Based on Threshold

In the step S35 of determining a defect of the battery 1, based on the threshold, that is performed at a second time, similar to the step S35 that is performed at a first time, the threshold is set for the inter-terminal voltage differences ΔV, excluding the maximum value ΔVmax and the minimum value ΔVmin. Herein, whether the battery 1 is defective is determined for the (N−2) batteries 1, excluding the two batteries determined to be defective in the step S35 that is performed at a first time.

Similar to the step S35 that is performed at the first time, the threshold Th is set based on the standard deviation σ calculated in the step S34 of calculating the standard deviation. Similar to the step S35 that is performed at the first time, the threshold Th is set to a value (3σ) three times the standard deviation σ. The threshold Th is not limited to the value described above.

Whether the battery 1 is defective is determined for the (N−2) batteries 1, based on the threshold Th. As illustrated in FIG. 7, in each of the (N−3) batteries 1 of the (N−2) batteries 1, the difference between the inter-terminal voltage difference ΔV and the average value ΔVa is equal to or smaller than the threshold Th. In the battery 1 of the (N−2) batteries 1 the inter-terminal voltage difference ΔV of which is highest, the difference between the inter-terminal voltage difference ΔV and the average value ΔVa is larger than the threshold Th. The battery 1 the inter-terminal voltage difference ΔV of which is highest is determined to be defective. When it is determined that there is the defective battery 1 (NO), the process proceeds to the step S36 again.

### Step S36 of Excluding Battery Determined to Be Defective

In the step S36 of excluding the battery determined to be defective, of the (N−2) batteries 1 except the two batteries that have been already excluded, one battery 1 determined to be defective is further excluded from targets of determination. The one battery 1 is excluded, and remaining (N−3) batteries 1 are targets of determination. The process returns to the step S32 of excluding at least one inter-terminal voltage difference.

### Step S32 of Excluding at Least One Inter-Terminal Voltage Difference

In the step S32 that is performed at a third time, similar processing to those of the step S32 performed at the first time and the second time is executed. The maximum and minimum inter-terminal voltage differences ΔV of the inter-terminal voltage differences ΔV of the remaining (N−3) batteries 1 are excluded. The threshold Th used for determining a defect of the battery 1 is set based on the inter-terminal voltage differences ΔV of remaining (N−5) batteries 1. As illustrated in FIG. 8, of the inter-terminal voltage differences ΔV of the multiple batteries 1, the maximum value ΔVmax and the minimum value ΔVmin are excluded. Herein, the maximum and minimum inter-terminal voltage differences ΔV of the inter-terminal voltage differences ΔV of the (N−3) batteries 1 are excluded. The threshold Th used for determining a defect of the battery 1 is set again based on the inter-terminal voltage differences ΔV of the remaining (N−5) batteries 1. Note that the minimum ΔVmin is the same as that excluded in the step S32 that has been performed at the first time.

### Step S33 of Calculating Average Value of Inter-Terminal Voltage Difference, Step S34 of Calculating Standard Deviation of Inter-Terminal Voltage Difference

In the step S33 of calculating the average value of the inter-terminal voltage differences that is performed at a third time, the average value of the inter-terminal voltage differences ΔV of the (N−5) batteries 1, excluding the maximum value ΔVmax and the minimum value ΔVmin, is calculated. In this embodiment, the average value ΔVa is 0.0167. In the step S34 of calculating the standard deviation of the inter-terminal voltage differences that is performed at a third time, similar to the step S33 of calculating the average value, the standard deviation σ of the inter-terminal voltage differences ΔV of the (N−5) batteries 1, excluding the maximum value ΔVmax and the minimum value ΔVmin, is calculated. In this embodiment, the standard deviation σ is 0.0055.

### Step S35 of Determining Defect of Battery 1 Based on Threshold

In the step S35 of determining a defect of the battery 1 based on the threshold that is performed at a third time, similar to the step S35 performed at the first time and the second time, the threshold is set for the inter-terminal voltage differences ΔV, excluding the maximum value ΔVmax and the minimum value ΔVmin. Herein, whether the battery 1 is defective is determined for the (N−3) batteries 1, excluding one battery determined to be defective in the step S35 performed at the second time. Similar to the step S35 preformed at the first time and the second time, the threshold Th is set to a value (3 σ) three times the standard deviation σ.

Whether the battery 1 is defective is determined for the (N−3) batteries 1, based on the threshold Th. As illustrated in FIG. 8, the difference between the inter-terminal voltage difference ΔV and the average value ΔVa is equal to or smaller than the threshold Th in all of the (N−3) batteries 1 that are targets of determination. When it is determined that there is no defective battery 1 (YES), the process proceeds the step S37.

### Step S37 of Determining Whether Determination of Defect Has Been Repeated Predetermined Number of Times

In the step S37 of determining whether determination of a defect has been repeated a predetermined number of times, whether the number of times determination of the step S35 has been performed has reached the predetermined number of times is determined. The number of times determination of the step S35 is to be performed is set to about five to ten times, although there is no particular limitation thereon. Herein, the number of times determination of the step S35 has been performed is three times, and therefore, it is determined the number of times determination of the step S35 has not reached the predetermined number of times (NO), the process returns to the step S32.

When the step S32 to the step S37 described above are repeated and it is determined in the step S37 that the number of times determination of a defect reaches the predetermined number of times (YES), the determining step S30 ends. In other words, determination on whether each of the multiple batteries 1 is defective based on the respective inter-terminal voltage differences ΔV before and after aging processing of the multiple batteries 1 ends. In the determining step S30, of the N batteries 1 that are targets of determination, three batteries 1 were determined to be defective.

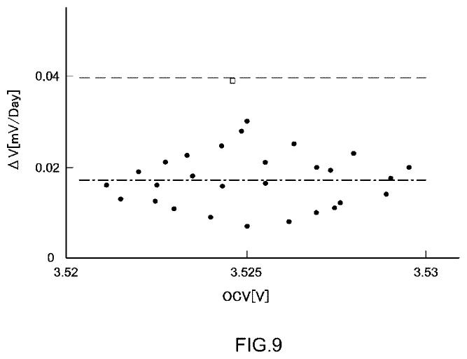

Another embodiment in which, of the determining step S30 described above, the step S32 of excluding at least one inter-terminal voltage difference is not performed will be described below. FIG. 9 is a graph illustrating the inter-terminal voltage differences ΔV after excluding the defective battery 1 according to another embodiment.

As described above, in the embodiment illustrated in FIG. 5, the average value ΔVa of the inter-terminal voltage differences ΔV of the N batteries 1 is 0.0272 and the standard deviation σ is 0.0390. When the step S32 is not performed, as illustrated in FIG. 5, of the N batteries 1 that are targets of determination, the battery 1 the inter-terminal voltage difference ΔV of which is highest and the battery 1 the inter-terminal voltage difference ΔV of which is second highest are determined to be defective. The two batteries 1 determined to be defective are excluded from the targets of determination.

When the average value ΔVa of the inter-terminal voltage differences ΔV of remaining (N−2) batteries 1 is 0.0175 and the standard deviation σ is 0.0073. When the step S32 is not performed, as illustrated in FIG. 9, the difference between the inter-terminal voltage difference ΔV and the average value ΔVa is equal to or smaller than the threshold Th for all of the (N−2) batteries 1 that are targets of determination. When it is determined that there is no defective battery 1 and the number of times determination has been performed reaches the predetermined number of times, the determination step ends.

In the embodiment illustrated in FIG. 9, the inter-terminal voltage difference ΔV of one battery 1 of the (N−2) batteries 1 that are targets of determination (indicated by a square in FIG. 9) has a large deviation, as compared to the inter-terminal voltage differences ΔV of the other (N−3) batteries 1. The inter-terminal voltage difference ΔV of the one battery 1 is higher than the average value by a value that is 2.91 times the standard deviation. The inter-terminal voltage difference ΔV of the one battery 1 is an extremely large value (a so-called outlier) as compared to the inter-terminal voltage difference ΔV of the other (N−3) batteries 1. According to a finding of the inventor, when the deviation is large, as compared to the inter-terminal voltage differences ΔV of the other batteries 1, there is a possibility that a malfunction, such as a minute short circuit or the like, has occurred in the one battery 1. When the inter-terminal voltage difference ΔV of an outlier with which there is a possibility that a malfunction has occurred is included in calculation of the threshold Th, the threshold Th is less likely to be set properly due to the inter-terminal voltage difference ΔV of the outlier. For example, when a defect of the battery 1 is determined based on the average value ΔVa of the inter-terminal voltage differences ΔV of the multiple batteries 1 and the standard deviation σ, the standard deviation σ is large and the threshold Th can be set broadly. In this case, in determination of a defect of the battery (in this embodiment, the step S35), the battery 1 in which there is a possibility that a malfunction has occurred is less likely to be determined to be defective. In order to determine such a battery 1 to be defective, it is considered to set the threshold Th strictly. For example, when the threshold Th is set by multiplying the standard deviation σ by the value n, a small value can be selected as n. However, when the threshold Th is set strictly, there is a concern that the battery 1 in which there is no malfunction is determined to be defective.

In the embodiment described above, the method for manufacturing a battery includes the step (step S21) of acquiring the inter-terminal voltage V1 before aging processing for the multiple batteries 1, the step (step S22) of performing aging processing on the multiple batteries 1, the step (step S23) of acquiring the inter-terminal voltage V2 after aging processing for the multiple batteries 1, and the step (step S30) of determining, for each of the multiple batteries 1, whether the battery 1 is defective. In the step of determining, for each of the multiple batteries 1, whether the battery 1 is defective, at least one inter-terminal voltage difference ΔV is excluded from the respective inter-terminal voltage differences ΔV before and after aging processing of the multiple batteries 1 and thus the threshold Th is set. In the method for manufacturing a battery described above, in setting the threshold Th, the threshold Th can be set in a state where the inter-terminal voltage difference ΔV with a large deviation, as compared to the inter-terminal voltage differences ΔV of the other batteries 1, is excluded. Thus, it can be prevented that the threshold Th (in this embodiment, the standard deviation σ) is set broadly due to the inter-terminal voltage difference ΔV with a large deviation. As a result, the threshold Th is likely to be set properly. Since the threshold Th is set properly, the battery 1 the inter-terminal voltage difference ΔV of which is an outlier, as compared to the other batteries 1 (the battery 1 in which there is a possibility that a malfunction, such as a minute short circuit or the like, has occurred) is likely to be determined to be defective. As a result, accuracy of determination of a defect of the battery 1 is increased.

In the embodiment described above, at least one inter-terminal voltage difference ΔV is the maximum value ΔVmax and the minimum value ΔVmin of the inter-terminal voltage differences ΔV of the multiple batteries 1. When the maximum value ΔVmax and the minimum value ΔVmin of the inter-terminal voltage differences ΔV are excluded, it is likely that the inter-terminal voltage difference ΔV with a large deviation is excluded in setting the threshold Th. Either when the battery 1 the inter-terminal voltage difference ΔV of which is extremely large, as compared to the other batteries 1, is included or when the battery 1 the inter-terminal voltage difference ΔV of which is extremely small, it is likely that the inter-terminal voltage difference ΔV with a large deviation is excluded. As a result, the threshold Th is likely to be set properly.

Note that, in the embodiment described above, the maximum value ΔVmax and the minimum value ΔVmin of the inter-terminal voltage differences ΔV are excluded, but some other one of the inter-terminal voltage differences ΔV of the multiple batteries 1 may be excluded such that the maximum value ΔVmax and the minimum value ΔVmin of the inter-terminal voltage differences ΔV are included. For example, the maximum value ΔVmax and a second highest value of the multiple inter-terminal voltage differences ΔV may be excluded. The minimum value ΔVmin and a second smallest value of the inter-terminal voltage differences ΔV may be excluded. The number of the inter-terminal voltage differences ΔV that are excluded may be three or more.

When a rate at which a defect of the battery 1 occurs has been acquired in advance, the number of the inter-terminal voltage differences ΔV that are excluded may be set based on the rate (malfunction occurrence rate). Thus, the inter-terminal voltage difference ΔV with a large deviation is likely to be excluded properly and the threshold Th is likely to be set properly. Note that the number of the inter-terminal voltage differences ΔV that are excluded can be set to a number obtained by multiplying the number of the batteries 1 that are targets of determination by the malfunction occurrence rate. The malfunction occurrence rate can be acquired, for example, from a mass production test, a mass production performance, or the like.

In the embodiment described above, the step S20 of determining a defect of the battery includes excluding the battery 1 determined to be defective from the multiple batteries 1 (the step S36). The step S20 of determining a defect of the battery also includes setting the threshold Th, based on the standard deviation σ calculated further excluding at least one inter-terminal voltage difference ΔV from the inter-terminal voltage differences ΔV of the multiple batteries 1, excluding the battery 1 determined to be defective, and repeating determination of the battery that is defective (the steps S35 and S36). Since the threshold Th is set again in a state where the battery 1 determined to be defective has been excluded in advance, the threshold Th is likely to be set properly in a stepwise manner. As a result, the threshold Th is likely to be set properly.

In the embodiment described above, the number of the batteries 1 that are targets of determination is N. The number of the batteries 1 that are targets of determination is preferably seven or more. Thus, the threshold Th used for determining a defect of the battery 1 is likely to be set properly in accordance with the method described above. Note that the number of the batteries 1 that are targets of determination is not limited to the number described above.

In the embodiment described above, the threshold Th is set based on the standard deviation σ. The threshold Th is not limited thereto, but may be a value predetermined based on a mass production test, a mass production performance, a degree of a minute short circuit that is to be determines as a defect, or the like.

The method for manufacturing a battery described above is applicable to a method for testing a battery, when the inter-terminal voltage differences before and after aging processing have been acquired in advance. Accuracy of determination of a battery in which a malfunction has occurred to be defective is increased by the method.

The technology disclosed herein has been described above in various forms. However, the embodiments described above or the like shall not limit the present disclosure, unless specifically stated otherwise. Various changes can be made to the technology disclosed herein, and each of components and processes described herein can be omitted as appropriate or can be combined with another one or other ones of the components and the processes as appropriate, unless a particular problem occurs. The present specification includes disclosure set forth in the following items.

First Item: A method for manufacturing a battery, the method including steps of performing aging processing on multiple batteries, acquiring an inter-terminal voltage before the aging processing for the multiple batteries, acquiring an inter-terminal voltage after the aging processing for the multiple batteries, and setting a threshold excluding at least one inter-terminal voltage difference from inter-terminal voltage differences between the inter-terminal voltages before and after the aging processing for the multiple batteries and determining, for each of the multiple batteries, whether the battery is defective.

Second Item: The method for manufacturing a battery according to the first item, in which the determining includes excluding a battery determined to be defective from the multiple batteries, and setting a threshold, based on a standard deviation calculated further excluding at least one inter-terminal voltage difference from the inter-terminal voltage differences of the multiple batteries excluding the battery determined to be defective, and repeating determination of a defective battery a predetermined number of times.

Third Item: The method for manufacturing a battery according to the first or second item, in which the at least one inter-terminal voltage difference includes a maximum value and a minimum value of the inter-termina voltage differences of the multiple batteries.

Fourth Item: The method for manufacturing a battery according to any one of the first to third items, in which a number of the multiple batteries is seven or more.

Fifth Item: The method for manufacturing a battery according to any one of the first to fourth items, in which a rate at which a defect of the battery occurs is acquired in advance and a number of inter-terminal voltage differences that are excluded is set based on the rate.

Sixth Item: A method for testing a battery, the method including steps of acquiring an inter-terminal voltage before aging processing for multiple batteries, acquiring an inter-terminal voltage after the aging processing for the multiple batteries, and setting a threshold excluding at least one inter-terminal voltage difference from inter-terminal voltage differences between the inter-terminal voltages before and after the aging processing for the multiple batteries and determining, for each of the multiple batteries, whether the battery is defective.

Seventh Item: The method for testing a battery according to the sixth item, in which the determining includes excluding a battery determined to be defective from the multiple batteries, and setting a threshold, based on a standard deviation calculated further excluding at least one inter-terminal voltage difference from the inter-terminal voltage differences of the multiple batteries excluding the battery determined to be defective, and repeating determination of a defective battery a predetermined number of times.

Eighth Item: The method for testing a battery according to the sixth or seventh item, in which the at least one inter-terminal voltage difference includes a maximum value and a minimum value of the inter-termina voltage differences of the multiple batteries.

Ninth Item: The method for testing a battery according to any one of the sixth to eighth items, in which a number of the multiple batteries is seven or more.

Tenth Item: The method for testing a battery according to any one of the sixth to ninth items, in which a rate at which a defect of the battery occurs is acquired in advance and a number of inter-terminal voltage differences that are excluded is set based on the rate.

What is claimed is:

1. A method for manufacturing a battery, the method comprising steps of:
performing aging processing on multiple batteries;
acquiring an inter-terminal voltage before the aging processing for the multiple batteries;
acquiring an inter-terminal voltage after the aging processing for the multiple batteries; and
setting a threshold excluding at least one inter-terminal voltage difference from inter-terminal voltage differences between the inter-terminal voltages before and after the aging processing for the multiple batteries and determining, for each of the multiple batteries, whether the battery is defective.

2. The method for manufacturing a battery according to claim 1, wherein the determining includes
excluding a battery determined to be defective from the multiple batteries, and
setting a threshold, based on a standard deviation calculated further excluding at least one inter-terminal voltage difference from the inter-terminal voltage differences of the multiple batteries excluding the battery determined to be defective, and repeating determination of a defective battery a predetermined number of times.

3. The method for manufacturing a battery according to claim 1, wherein
the at least one inter-terminal voltage difference includes a maximum value and a minimum value of the inter-termina voltage differences of the multiple batteries.

4. The method for manufacturing a battery according to claim 1, wherein
a number of the multiple batteries is seven or more.

5. The method for manufacturing a battery according to claim 1, wherein
a rate at which a defect of the battery occurs is acquired in advance and a number of inter-terminal voltage differences that are excluded is set based on the rate.

6. A method for testing a battery, the method comprising steps of:
acquiring an inter-terminal voltage before aging processing for multiple batteries;
acquiring an inter-terminal voltage after the aging processing for the multiple batteries; and
setting a threshold excluding at least one inter-terminal voltage difference from inter-terminal voltage differences between the inter-terminal voltages before and after the aging processing for the multiple batteries and determining, for each of the multiple batteries, whether the battery is defective.

7. The method for testing a battery according to claim 6, wherein
the determining includes
excluding a battery determined to be defective from the multiple batteries, and
setting a threshold, based on a standard deviation calculated further excluding at least one inter-terminal voltage difference from the inter-terminal voltage differences of the multiple batteries excluding the battery determined to be defective, and repeating determination of a defective battery a predetermined number of times.

8. The method for testing a battery according to claim 6, wherein
the at least one inter-terminal voltage difference includes a maximum value and a minimum value of the inter-termina voltage differences of the multiple batteries.

9. The method for testing a battery according to claim 6, wherein
a number of the multiple batteries is seven or more.

10. The method for testing a battery according to claim 6, wherein
a rate at which a defect of the battery occurs is acquired in advance and a number of inter-terminal voltage differences that are excluded is set based on the rate.
